(19) United States
(12) Patent Application Publication
(10) Pub. No.: US 2016/0259105 A1
(43) Pub. Date: Sep. 8, 2016

(54) DISPLAY DEVICE

(71) Applicant: SHENZHEN CHINA STAR OPTOELECTRONICS TECHNOLOGY CO., LTD., Shenzhen, Guangdong (CN)

(72) Inventors: Guofu TANG, Shenzhen, Guangdong (CN); Yuchun HSIAO, Shenzhen, Guangdong (CN)

(73) Assignee: Shenzhen China Star Optoelectronics Technology Co., Ltd., Shenzhen, Guangdong (CN)

(21) Appl. No.: 14/426,145

(22) PCT Filed: Oct. 15, 2014
(86) PCT No.: PCT/CN2014/088616

§ 371 Date: Mar. 4, 2015

(30) Foreign Application Priority Data
Sep. 29, 2014 (CN) 201410515564.9

(51) Int. Cl. G02B 5/30; G02B 1/14; H01L 51/52; G02F 1/1335

(52) U.S. Cl. CPC G02B 5/3025; G02F 1/133536; G02B 1/14; H01L 51/5271; G02F 2202/28; G02F 2001/133302

(57) ABSTRACT

A display device is disclosed, which it comprises a backlight module used for providing the backlight brightness of the display device; a display device used for displaying images; a first polarizer, located between the backlight module and the display module, and disposed on a lower surface of the display module, for transforming light from the backlight module into linear polarizing light; a mirror polarizer having polarization function, comprising a first thermosensitive glue layer, the mirror polarizer is bonded on an outer surface of the display module by a first thermosensitive glue layer for transmitting light from the backlight module and reflecting natural light at the same time. The display device of the present invention does not obviously increase the display panel thickness and weight, and has relatively lower cost. Also, it can be used in the LCD module and OLED display module.

### BACKGROUND OF THE INVENTION

1. Field of the Invention

The present invention relates to a display technology; particularly, to a display device.

2. Description of Related Art

At present, there are all kinds of the appearance mirror in some high classic place with some functions for example: appearance showing, message transmitting and displaying. It not only satisfies people's requirement for dressing up but also can be a billboard for advertising.

As shown in FIG. 1a, the achievement method is to bond a translucent and semi-reflective glass layer 3 on the display panel and the front frame 2 is used to fix the glass layer 3 on the outer surface of the display panel 1. The method has some issues which comprises loss transmittance and increasing the screen thickness and weight.

The market also has another method, as shown in FIG. 1b, a PDLC layer (polymer dispersed liquid crystal layer) 4 is added in the structure of the OLED display panel 1 to achieve the display control for mirror or display function.

### SUMMARY OF THE INVENTION

The present invention to solve the traditional technical problem is to provide a display device without increasing the display thickness, weight and cost, which can be used in the display devices of the liquid crystal display module and the OLED display module.

In order to achieve the purpose, the present invention adopts the following technical solution:

A display device, comprising: a backlight module, used for providing the backlight brightness of the display device; a display module, used for displaying images; a first polarizer, located between the backlight module and the display module, and disposed on a lower surface of the display module, for transforming light from the backlight module into linear polarizing light; a mirror polarizer having polarization function, comprising a first thermosensitive glue layer, the mirror polarizer is bonded on an outer surface of the display module by a first thermosensitive glue layer for transmitting light from the backlight module and reflecting natural light at the same time.

According to a preferred embodiment of the present invention, the mirror polarizer further comprises a first dichroic layer located at a front end of the first thermosensitive glue layer, and a first brightening layer, a second dichroic layer, and a second brightening layer, and the first dichroic layer and the second dichroic layer absorb polarization, and the first brightening layer and the second brightening layer reflects light.

According to a preferred embodiment of the present invention, the mirror polarizer further comprises a scratching-resistant layer located in a front end of the second brightening layer.

According to a preferred embodiment of the present invention, the scratching-resistant layer is a tri-cellulose acetate material.

According to a preferred embodiment of the present invention, the display device further comprises a second polarizer having polarization function, and the second polarizer is located between the display module and the mirror polarizer.

According to a preferred embodiment of the present invention, the display module comprises a TFT glass substrate, a liquid crystal layer and a CF glass substrate.

According to a preferred embodiment of the present invention, the display module is an OLED display module.

The display device of the present invention is to dispose a first polarizer having polarization function in the front end of the display device without increasing the thickness or weight of the display panel and the cost. Moreover, the display device of the present invention can be used in the LCD device and the OLED display module.

### BRIEF DESCRIPTION OF THE DRAWINGS

FIG. 1a is the schematic diagram of the conventional display device.

FIG. 1b is the other schematic diagram of the conventional display device.

FIG. 2 is the schematic diagram of the display device of the first embodiment of the present invention.

FIG. 3 is the schematic diagram of the mirror polarizer of the display device of the first embodiment of the present invention.

FIG. 4 is the schematic diagram of the optical path of the display device of the first embodiment of the present invention.

FIG. 5 is the schematic diagram of the display device of the second embodiment of the present invention.

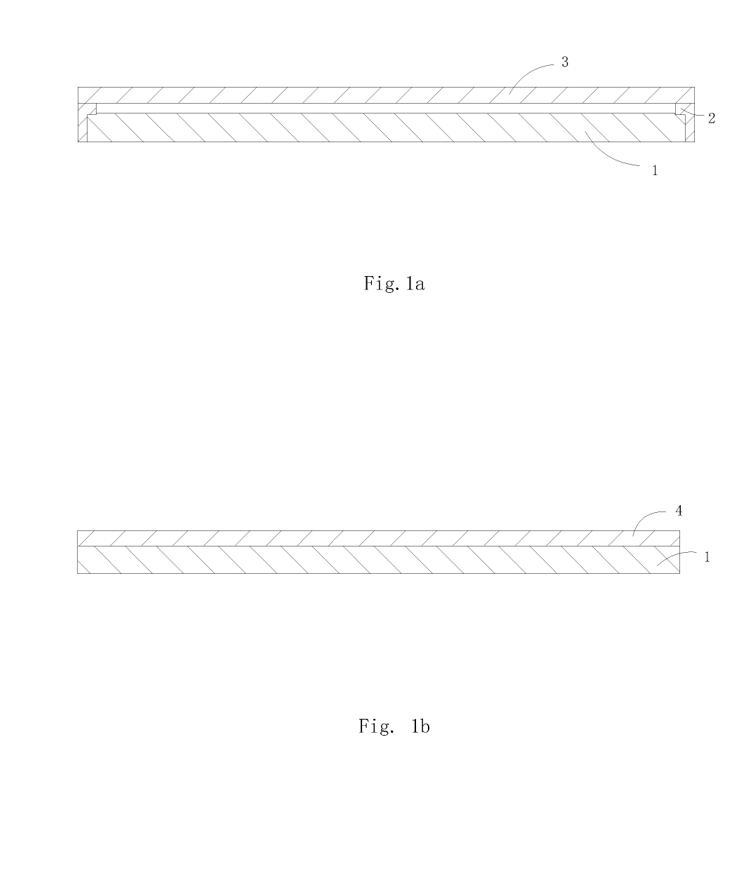

### DETAILED DESCRIPTION OF THE PREFERRED EMBODIMENTS

In order to understand the present invention well, the following examples combining with the accompanying drawings in detail.

### 1st Embodiment

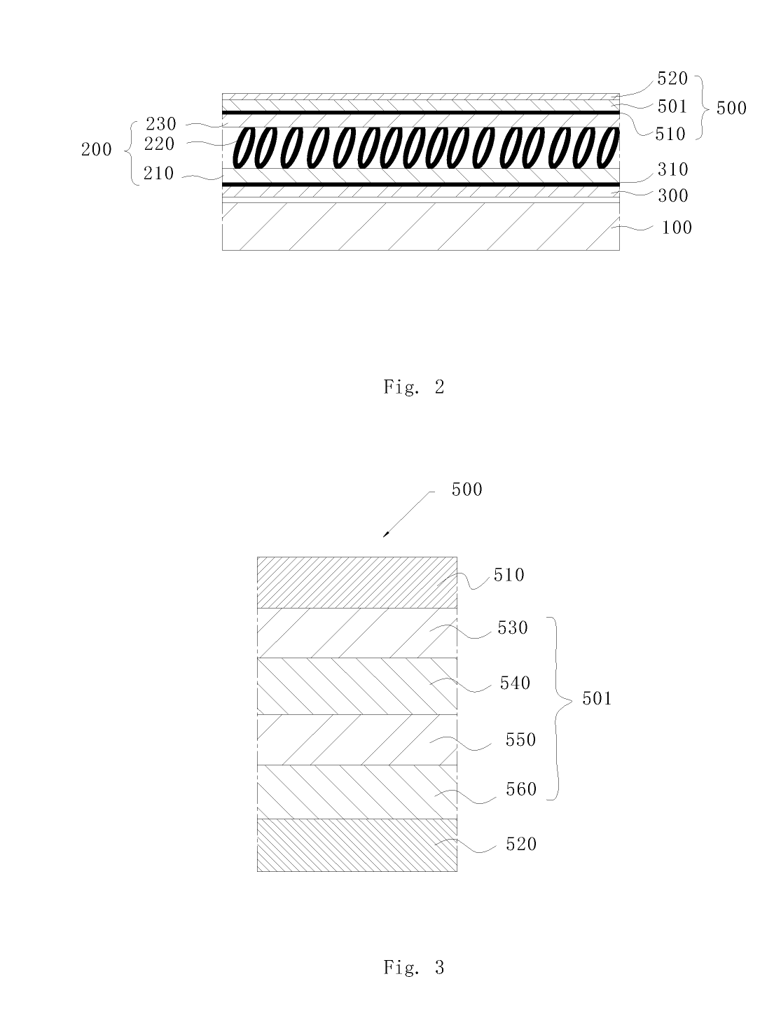

Please refer to FIG. 2 and FIG. 3. The display device of the first embodiment of the present invention comprises a backlight module 100, a display module 200, a first polarizer 300 and a mirror polarizer 500, where the backlight module 100 is used for providing the backlight brightness of the display device; the display module 200 is used for displaying images; the first polarizer 300 is located between the backlight module 100 and the display module 200 and disposed on the lower surface of the display module 200 for transmitting light from the backlight module 100 into the linear polarization light; the mirror polarizer 500 has polarization function and is disposed on the top surface of the display module 200 for transmitting the light from the backlight module 100 and at the same time reflecting the natural light.

A mirror polarizer 500 is disposed on the front end of the display device. When the side backlight brightness of the backlight module 100 is larger than the ambient light in the environment, the device appears the images displayed by the display module; when the brightness of the ambient light is larger than the brightness of the backlight of the backlight module, the display device appears the mirror effect. The display device of the present invention does not obviously increase the display panel thickness and weight, and has relatively lower cost. Also, it can be used in the LCD module and OLED display module so it has high technical commonality.

Specifically, the mirror polarizer 500 at least comprises the first thermosensitive glue layer 510 and a functional layer 501. The function layer of mirror polarizer 501 is bonded on the outer surface of the display module 200 by the first thermosensitive glue layer 510. The function layer 50a comprises the first dichroic layer 530 located at a front end of the first thermosensitive glue layer 510, a first brightening layer 540, a second dichroic layer 550, and a brightening layer 560 in order, where the first dichroic layer 530 and the second dichroic layer 550 absorb polarization, and the first brightening layer 540 and the second brightening layer 560 reflects light. Where, the first polarizer 300 is bonded on the lower surface of the display module 200 by the second thermosensitive glue layer 510. The first thermosensitive glue layer 510 and the second thermosensitive glue layer 310 are pressure sensitive adhesives (PSA) hereto.

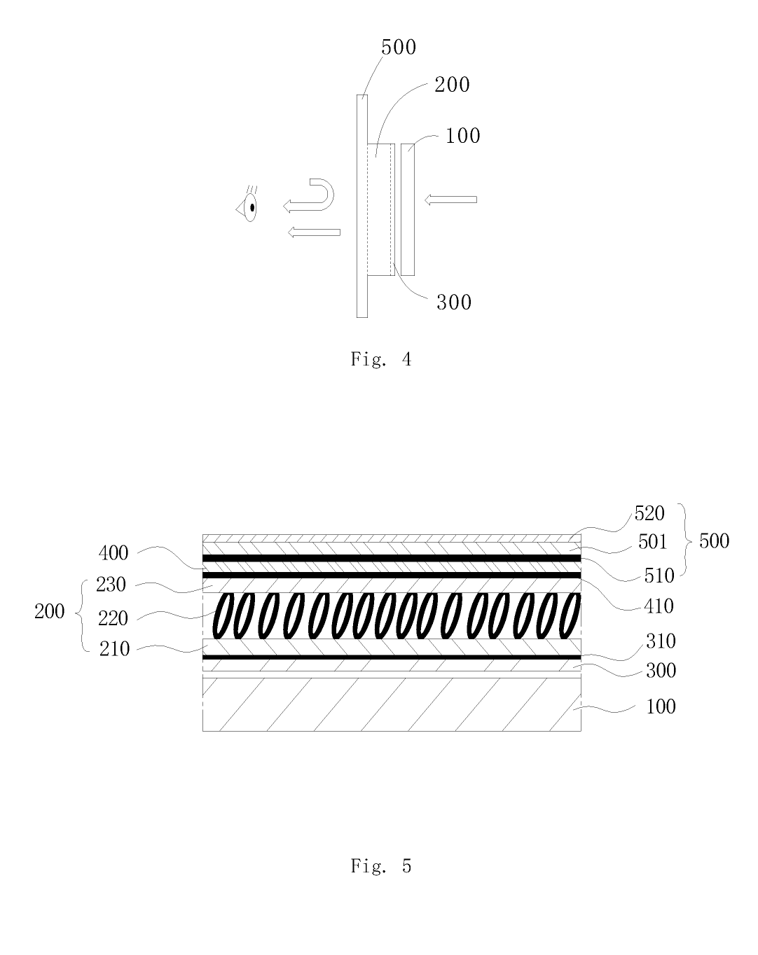

In the first embodiment, the first dichroic layer 530 and the second dichroic layer 550 are black to absorb the excessive optical vibration and only permit the optical vibration vertical to the first dichroic layer 530 and the second dichroic layer 550 to pass through them. The first brightening layer 540 and the brightening layer 560 are mirror structure and used for reflecting light. FIG. 4 is a schematic diagram of the optical path of the display module. The light from the backlight side passes through the backlight module 100 and the first polarizer 300 and then forms images on the display module 200. When the brightness of the source of the backlight module 100 is larger than the brightness of the ambient light and the light from the display module 200 passes through the mirror polarizer 500 into the visual range of the viewers, the display device shows the images of the display module 200. When the display panel appears in the state of dark images or turning off and the brightness of the ambient light is larger than the brightness of the backlight module 100, the ambient light is reflected back from the mirror polarizer 500 and the display device appears the mirror effect.

In order to prevent the display device from scratching due to the prolonged use and frequent touching, the mirror polarizer 500 further comprises a scratching-resistant layer 520. In the first embodiment, the scratching-resistant layer 520 is a tri-cellulose acetate (TAC) material having high hardness.

In the first embodiment, the display module comprises a TFT glass substrate 10, a liquid crystal layer 220 and a CF glass substrate 230. Specifically, the mirror polarizer 510 is bonded on the outer surface of the CF glass substrate 230 by the first thermosensitive glue layer 510, and the first polarizer 300 is bonded on the outer surface of the TFT glass substrate 210 by the second thermosensitive glue layer 310.

Where, the heat-conductive insulation layer 100 is a thermal-conductive insulation adhesive, and the heat-conductive insulation layer 100 is bonded on the lower surface of the cooling plate 60.

### 2nd Embodiment

The display device of the second embodiment also comprises a backlight module 100, a display module 200, a first polarizer 300 and a mirror polarizer 500. The difference with the first embodiment is that the display device of the second embodiment further comprises a second polarizer 400 having polarization function and the second polarizer 400 is located between the display module 200 and the mirror polarizer 500. Specifically, the second polarizer is bonded on the outer surface of the display module 200 by the third thermosensitive glue layer, and the mirror polarizer 500 is bonded on the second polarizer 400 by the first thermosensitive glue layer 510 to form a dual polarization structure.

It can be understood that the display module can be an OLED display module. Compared with the conventional art, the display device of the present invention does not increase the thickness or weight of the display panel with the lower cost and it can be used in the LCD device and the OLED display module.

The above are only specific embodiments of the present invention, it should be noted that those of ordinary skill in the art, in the present invention without departing from the principles of the premise, further improvements and modifications may be made, these improvements and modifications should also be regarded as the protection scope of the present invention.

What is claimed is:

1. A display device, comprising:
a backlight module, used for providing the backlight brightness of the display device;
a display module, used for displaying images;
a first polarizer, located between the backlight module and the display module, and disposed on a lower surface of the display module, for transforming light from the backlight module into linear polarizing light;
a mirror polarizer having polarization function, comprising a first thermosensitive glue layer, the mirror polarizer is bonded on an outer surface of the display module by a first thermosensitive glue layer for transmitting light from the backlight module and reflecting natural light at the same time.

2. The display device as claimed in claim 1, wherein the mirror polarizer further comprises a first dichroic layer located at a front end of the first thermosensitive glue layer, and a first brightening layer, a second dichroic layer, and a second brightening layer, and the first dichroic layer and the second dichroic layer absorb polarization, and the first brightening layer and the second brightening layer reflects light.

3. The display device as claimed in claim 2, wherein the mirror polarizer further comprises a scratching-resistant layer located in a front end of the second brightening layer.

4. The display device as claimed in claim 3, wherein the scratching-resistant layer is a tri-cellulose acetate material.

5. The display device as claimed in claim 1, further comprises a second polarizer having polarization function, and the second polarizer is located between the display module and the mirror polarizer.

6. The display device as claimed in claim 1, wherein the display module comprises a TFT glass substrate, a liquid crystal layer and a CF glass substrate.

7. The display device as claimed in claim 2, wherein the display module comprises a TFT glass substrate, a liquid crystal layer and a CF glass substrate.

8. The display device as claimed in claim 3, wherein the display module comprises a TFT glass substrate, a liquid crystal layer and a CF glass substrate.

9. The display device as claimed in claim 1, wherein the display module is an OLED display module.

10. The display device as claimed in claim 2, wherein the display module is an OLED display module.

11. The display device as claimed in claim 3, wherein the display module is an OLED display module.
